(19) United States
(12) Patent Application Publication
(10) Pub. No.: US 2026/0314068 A1
(43) Pub. Date: Oct. 8, 2026

(54) SEMICONDUCTOR DEVICE

(71) Applicant: Vanguard International Semiconductor Corporation, Hsinchu (TW)

(72) Inventors: Tsung-Hsiung LEE, Taoyuan City (TW); Chen-Dong TZOU, Taipei City (TW); Chia-Hao LEE, Zhubei City (TW)

(73) Assignee: Vanguard International Semiconductor Corporation, Hsinchu (TW)

(21) Appl. No.: 19/169,891

(22) Filed: Apr. 3, 2025

(51) Int. Cl. H10D 86/00; H10D 30/65; H10D 64/00

(52) U.S. Cl. CPC H10D 86/201; H10D 30/657; H10D 30/658; H10D 64/117

(57) ABSTRACT

A semiconductor device includes: a semiconductor on insulator (SOI) substrate; and a vertical active element disposed in a first region of the semiconductor on insulator substrate. The vertical active element includes: a pair of source regions disposed in the semiconductor on insulator substrate; a pair of gate electrodes disposed at opposite sides of the pair of source regions, respectively; a pair of drain electrodes disposed at opposite sides of the pair of gate electrodes, respectively; and a buried layer located below the pair of source regions and the pair of gate electrodes, and electrically connected to the pair of drain electrodes. The semiconductor device further includes: a horizontal active element disposed in a second region of the semiconductor on insulator substrate; and an isolation structure separating the vertical active element from the horizontal active element.

### BACKGROUND

### Technical Field

The present disclosure relates to a semiconductor device, and in particular, it relates to a design that integrates a vertical active element with a horizontal active element.

### Description of the Related Art

The semiconductor integrated circuit (IC) industry has experienced rapid growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, such scaling down has also been accompanied by increased complexity in design and manufacturing of devices incorporating these integrated circuits. As the minimum feature dimension is continuously reduced, the manufacturing process has become more difficult to implement. Therefore, the formation of a reliable semiconductor device with smaller feature size is very challenging.

### SUMMARY

An embodiment of the present disclosure provides a semiconductor device includes: a semiconductor on insulator (SOI) substrate; and a vertical active element disposed in a first region of the semiconductor on insulator substrate. The vertical active element includes: a pair of source regions disposed in the semiconductor on insulator substrate; a pair of gate electrodes disposed at opposite sides of the pair of source regions, respectively; a pair of drain electrodes disposed at opposite sides of the pair of gate electrodes, respectively; and a buried layer located below the pair of source regions and the pair of gate electrodes, and electrically connected to the pair of drain electrodes. The semiconductor device further includes: a horizontal active element disposed in a second region of the semiconductor on insulator substrate; and an isolation structure separating the vertical active element from the horizontal active element.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIGS. 1-5 illustrate cross-sectional views of intermediate stages of a semiconductor device, according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity, and does not in itself dictate a relationship between various embodiments and/or configuration discussed.

Furthermore, in some embodiments of the present disclosure, terms that describe a joining or connecting action, such as “connect”, “interconnect”, or the like, unless otherwise defined, may include embodiments in which two features are formed in direct contact, and they may also include embodiments in which additional features may be formed between the two features.

Furthermore, spatially relative terms, such as “beneath,” “below,” “lower,” “on,” “above,” “upper,” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean ±20% of the stated value, more typically ±10% of the stated value, more typically ±5% of the stated value, more typically ±3% of the stated value, more typically ±2% of the stated value, more typically ±1% of the stated value, and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Some embodiments of the disclosure are described. Additional operations can be provided before, during, and/or after the stages described in these embodiments. Additional features can be added to the semiconductor device structure. Some of the features described below can be replaced or eliminated for different embodiments. Although some embodiments are discussed with operations performed in a particular order, these operations may be performed in another logical order.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

In the present technology, a horizontal active element (for example, a lateral-diffused metal-oxide semiconductor (LDMOS) transistor) may typically generate sufficiently high breakdown voltage and sufficiently low on-state resistance by adjusting the doping concentration and structural profile of every semiconductor region of the horizontal active element, in order to further optimize the overall performance. However, in a more complex design of the horizontal active element (for example, an integrated bipolar complementary metal oxide semiconductor—double diffused metal oxide semiconductor (BCD) transistor), it may be difficult to achieve an effective isolation.

In addition, a present vertical active element may include a metal-oxide semiconductor field effect transistor (MOSFET), for example, adopting a split-gate transistor (SGT) to maintain the breakdown voltage and to reduce the on-state resistance. The arrangement of the “split-gate” structure may drive the electric field from the frontside of the base plate toward the drain terminal at the backside of the base plate, thereby increasing the breakdown voltage and decreasing the on-state resistance.

It should be appreciated that the channel of the horizontal active element may be extended in the horizontal direction, while the channel of the vertical active element may be extended in the vertical direction. Therefore, if the horizontal active element and the vertical active element are to be disposed onto the same wafer, the present technology may need to form the horizontal active element and the vertical active element in different manufacturing processes. Furthermore, since it is already difficult to achieve the effective isolation in the horizontal active element, the isolation may be even more challenging when the horizontal active element and the vertical active element are integrated. The inventor has discovered that a semiconductor on insulator (SOI) substrate may be combined with a deep trench isolation (DTI) structure to achieve the complete isolation. Moreover, in response to the implementation of the semiconductor on insulator substrate, an innovative drain terminal may be constituted by electrically connecting metal sinkers with a buried layer, which are configured on the same side as the source terminal and the gate terminal (for example, on the frontside surface of the semiconductor on insulator substrate).

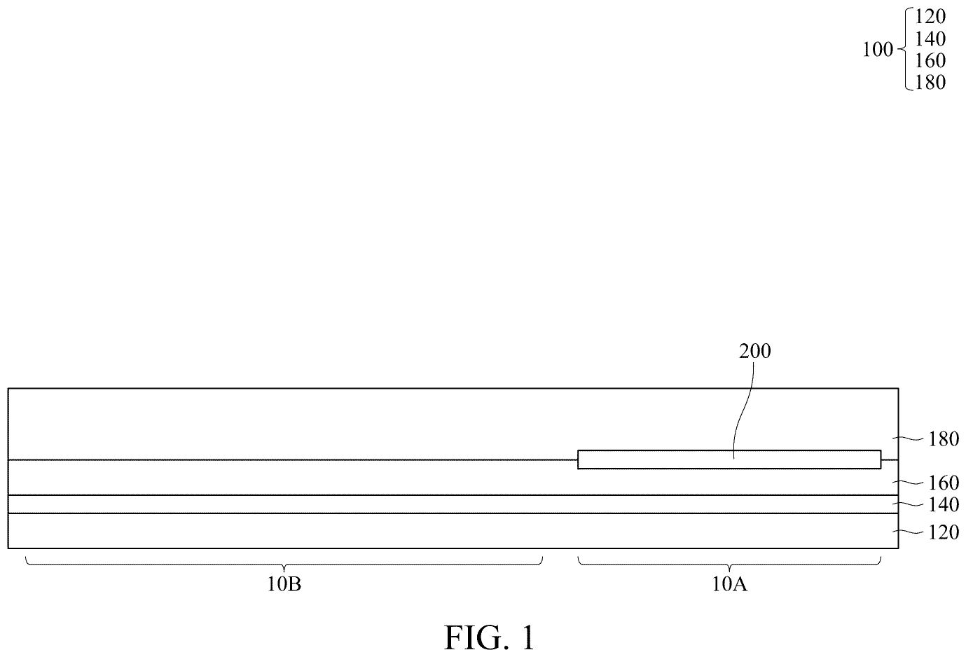

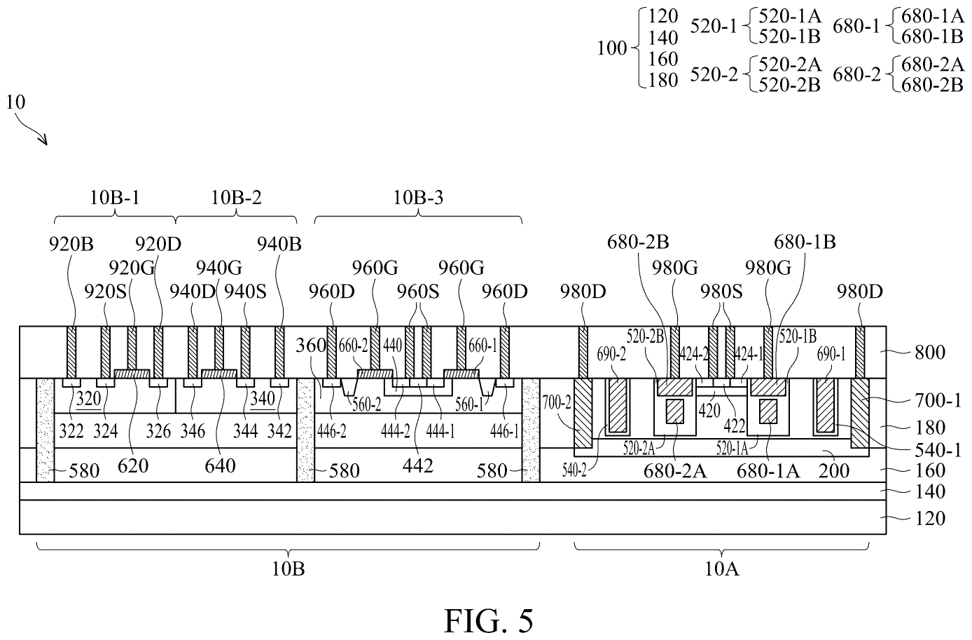

FIGS. 1-5 illustrate cross-sectional views of intermediate stages of a semiconductor device 10, according to some embodiments of the present disclosure. In the present embodiment, the semiconductor device 10 only illustrates a portion of the horizontal active element and a portion of the vertical active element. In some embodiments, a semiconductor device may typically include any quantity of active components or passive components. The active components include metal-oxide semiconductor (MOS) transistors, complementary metal-oxide semiconductor (CMOS) transistors, lateral-diffused metal-oxide semiconductor transistors, bipolar complementary metal oxide semiconductor—double diffused metal oxide semiconductor transistors, planar transistors, fin field-effect transistors (finFET), gate-all-around field-effect transistors (GAA FET), split-gate transistor, the like, or a combination thereof. The passive components include metal lines, capacitors, inductors, resistors, diodes, bonding pads, or the like. For simplicity, FIG. 5 only shows illustrative bipolar complementary metal oxide semiconductor—double diffused metal oxide semiconductor transistor and split-gate transistor.

Referring to FIG. 1, the semiconductor device 10 may be compartmentalized into a first region 10A and a second region 10B. The initial structure of the semiconductor device 10 may include a semiconductor on insulator substrate 100 and a buried layer 200. In some embodiments, the semiconductor on insulator substrate 100 may include a base plate 120, an insulating layer 140, an epitaxial layer 160, and an epitaxial layer 180. In other embodiments, the semiconductor on insulator substrate 100 may only include the base plate 120, the insulating layer 140, and the epitaxial layer 160, while the epitaxial layer 180 may be an additional semiconductor layer.

In some embodiments, the base plate 120 of the semiconductor on insulator substrate 100 may be, for example, a wafer or a chip, but the present disclosure is not limited thereto. In some embodiment, the base plate 120 may be a semiconductor substrate, for example, silicon (Si) substrate. Furthermore, in some embodiments, the semiconductor substrate may also be an elemental semiconductor including germanium (Ge), a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenic phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenic phosphide (GaInAsP) alloy, or a combination thereof.

Furthermore, the base plate 120 may be a first conductive type or a second conductive type that is different from the first conductive type. In the following embodiments, the first conductive type and the second conductive type may represent p-type and n-type, respectively. The first conductive type (p-type) and the second conductive type (n-type) may be respectively doped with suitable dopants (or impurities). P-type dopants may include boron (B), indium (In), aluminum (Al), or gallium (Ga), while n-type dopants may include phosphorus (P) or arsenic (As). In a specific embodiment of the present disclosure, the base plate 120 may be the second conductive type (n-type), with a doping concentration between 3×10¹⁹ cm⁻³ and 8×10¹⁹ cm⁻³.

Still referring to FIG. 1, the insulating layer 140 may be disposed on the base plate 120. In some embodiments, the insulating layer 140 may encapsulate the base plate 120, and may be continuously extended across the first region 10A and the second region 10B. According to some embodiments of the present disclosure, the insulating layer 140 may provide insulation for the overlying structures from the underlying substrate 120. The insulating layer 140 may be a buried oxide (BOX). The thickness of the insulating layer 140 may be between 0.5 μm and 5 μm.

Referring to FIG. 1, the epitaxial layer 160 may be disposed on the insulating layer 140. In some embodiments, the epitaxial layer 160 may have the second conductive type (n-type), with a doping concentration between 6×10¹⁵ cm⁻³ and 2×10¹⁷ cm⁻³. In a specific embodiment of the present disclosure, the base plate 120 and the epitaxial layer 160 may have the same conductive type, and the doping concentration of the base plate 120 is larger than the doping concentration of the epitaxial layer 160. The materials of the epitaxial layer 160 may include silicon, silicon germanium, silicon carbide, the like, or a combination thereof. The thickness of the epitaxial layer 160 may be between 1 μm and 7 μm. The epitaxial layer 160 may be formed by epitaxial process, which may include metal organic chemical vapor deposition (MOCVD), liquid phase epitaxy (LPE), vapor phase epitaxy (VPE), hydride vapor phase epitaxy (HVPE), selective epitaxial growth (SEG), molecular beam epitaxy (MBE), the like, or a combination thereof.

Still referring to FIG. 1, the epitaxial layer 180 may be disposed on the epitaxial layer 160. In some embodiments, the epitaxial layer 180 may have the second conductive type (n-type), with a doping concentration between 6×10¹⁵ cm⁻³ and 2×10¹⁷ cm⁻³. In a specific embodiment of the present disclosure, the base plate 120, the epitaxial layer 160, and the epitaxial layer 180 may all have the same conductive type, and the doping concentration of the epitaxial layer 160 is larger than the doping concentration of the epitaxial layer 180. The epitaxial layer 160 may be disposed between the insulating layer 140 and the epitaxial layer 180. The thickness of the epitaxial layer 180 may be between 1 μm and 7 μm. The materials and the formation of the epitaxial layer 180 may be similar to those of the epitaxial layer 160, and the details are not described again herein to avoid repetition.

It should be appreciated that since the subsequently formed discrete device is the second conductive type (n-type), the base plate 120, the epitaxial layer 160, and the epitaxial layer 180 all need to be the second conductive type (n-type), in order to facilitate the current conduction in the vertical channel. If the epitaxial layer 160 and the epitaxial layer 180 are both configured to be the first conductive type (p-type), an additional well region of the second conductive type (n-type) may be formed surrounding the discrete device (for example, the split-gate transistor), so the discrete device may continue to operate normally. Furthermore, the epitaxial layer 160 may be configured to have a relatively higher doping concentration to reduce the overall on-state resistance of the discrete device, while the epitaxial layer 180 may be configured to have a relatively lower doping concentration to maintain the overall breakdown voltage of the discrete device.

Referring to FIG. 1, the semiconductor device 10 may include the buried layer 200 disposed within the epitaxial layer 160 and within the epitaxial layer 180. In some embodiments, the buried layer 200 may have the second conductive type (n-type). According to some embodiments of the present disclosure, the buried layer 200 may be electrically connected to the subsequently formed drain electrode 700-1 and drain electrode 700-2 of the discrete device (for example, the split-gate transistor), and may function as an extension for the drain terminal. The vertical dimension of the buried layer 200 may be between 0.5 μm and 2 μm. The lateral dimension of the buried layer 200 may span across the subsequently formed drain electrode 700-1 and drain electrode 700-2. The formation of the buried layer 200 may include ion implanting the n-type dopants (for example phosphorus or arsenic) in the epitaxial layer 160 and performing thermal treatment to drive in the implanted ions into the epitaxial layer 160 before forming the epitaxial layer 180. After that, the epitaxial layer 180 may then be formed on the epitaxial layer 160. In some embodiments, since the epitaxial layer 180 is formed under the high temperature condition, thus the implanted ions may be diffused into the epitaxial layer 180. As shown in FIG. 1, the buried layer 200 is located near the interface between the epitaxial layer 160 and the epitaxial layer 180, with a portion in the epitaxial layer 160, and another portion in the epitaxial layer 180. In other words, the buried layer 200 may be extended upward and downward from the interface between the epitaxial layer 160 and the epitaxial layer 180.

In some embodiments, the doping concentration of the buried layer 200 may be between 5×10¹⁷ cm⁻³ and 1×10²⁰ cm⁻³. According to some embodiments of the present disclosure, the doping concentration of the base plate 120 may be larger than the doping concentration of the buried layer 200, the doping concentration of the buried layer 200 may be larger than the doping concentration of the epitaxial layer 160, and the doping concentration of the epitaxial layer 160 may be larger than the doping concentration of the epitaxial layer 180. The configuration of the epitaxial layer 160 with the relatively higher doping concentration below the buried layer 200, and the configuration of the epitaxial layer 180 with the relatively lower doping concentration above the buried layer 200 may be an ideal design to further reduce the on-state resistance. It should be appreciated that the buried layer 200 of the present disclosure may function to direct the current in the channel toward the subsequently formed drain electrode 700-1 and drain electrode 700-2. In order to electrically connect to the drain electrode 700-1 and the drain electrode 700-2, the doping concentration of the buried layer 200 needs to be sufficiently low, but still needs to be higher than the doping concentration of the epitaxial layer 160 and the epitaxial layer 180.

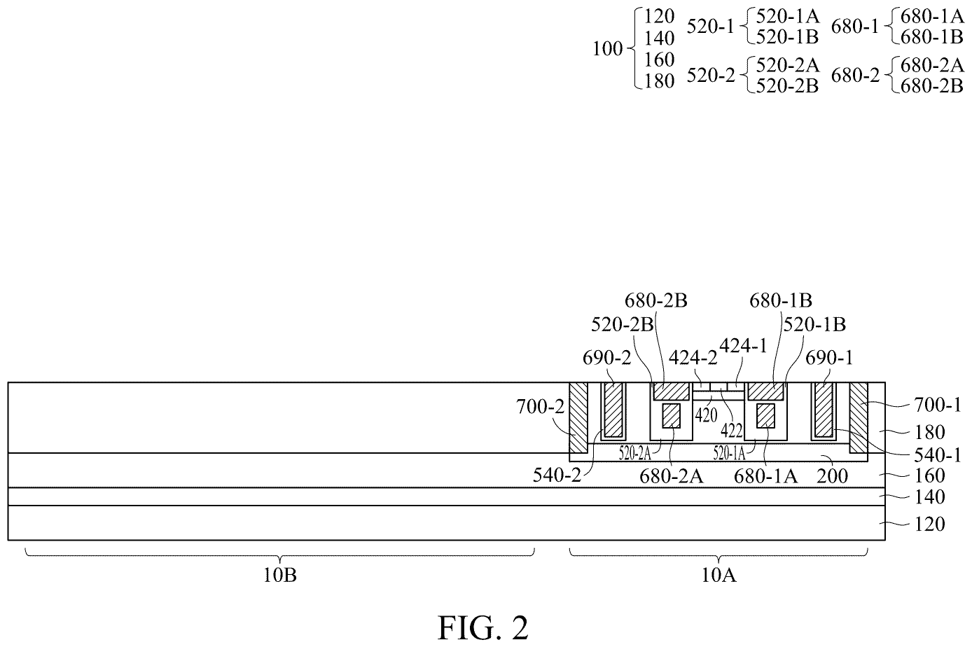

Referring to FIG. 2, the vertical active element may be disposed in the first region 10A of the semiconductor on insulator substrate 100, in which the vertical active element may be the discrete device. Although the semiconductor device 10 illustrates the split-gate transistor as the example of the discrete device, but the present disclosure is not limited thereto. For example, the discrete device may include switch trench metal-oxide semiconductor transistor or vertical-diffused metal-oxide semiconductor transistor. In a conventional split-gate transistor, the source terminal and the gate terminal may be configured at the frontside of the base plate, while the drain terminal may be configured at the backside of the base plate. Therefore, the channel may be formed extending from the frontside surface of the transistor toward the drain terminal on the backside of the base plate in the vertical direction.

It is worth noted that the semiconductor on insulator substrate 100 is implemented in order to integrate the horizontal active element and the vertical active element, and to achieve the complete isolation. If the drain terminal of the split-gate transistor is still disposed on the backside of the semiconductor on insulator substrate 100, then the insulating layer 140 would sever the original channel path. According to some embodiments of the present disclosure, the drain terminal of the split-gate transistor may be disposed at the frontside surface, in which the drain terminal may include the subsequently formed drain electrode 700-1 and drain electrode 700-2, as well as the buried layer 200 electrically connected to the drain electrode 700-1 and the drain electrode 700-2. The split-gate transistor in the first region 10A may still have the channel in the vertical direction. However, when the channel reaches the buried layer 200, the current may be directed toward both the drain electrode 700-1 and the drain electrode 700-2 along the buried layer 200 to achieve an effective operation for the split-gate transistor.

Initially, the well region 420 may be disposed within the epitaxial layer 180. The well region 420 may be extended vertically from the upper surface of the epitaxial layer 180 into the epitaxial layer 180. In some embodiments, the well region 420 may include the subsequently formed heavily doped region 422, source region 424-1, and source region 424-2. According to some embodiments of the present disclosure, the well region 420 may be the first conductive type (p-type), with a doping concentration between 1×10¹⁵ cm⁻³ and 2×10¹⁷ cm⁻³. The depth of the well region 420 may be between 0.3 μm and 1.5 μm. The well region 420 may be formed by, for example, the ion implantation and/or the diffusion process.

Still referring to FIG. 2, the heavily doped region 422, the source region 424-1, and the source region 424-2 may be disposed within the well region 420, and may be extended downward from the upper surface of the well region 420. According to some embodiments of the present disclosure, the heavily doped region 422 may be the first conductive type (p-type), while the source region 424-1 and the source region 424-2 may be the second conductive type (n-type). The heavily doped region 422, the source region 424-1, and the source region 424-2 may be laterally adjoined with each other, and the heavily doped region 422 may be laterally sandwiched between the source region 424-1 and the source region 424-2. The formation of the heavily doped region 422, the source region 424-1, and the source region 424-2 may be similar to that of the well region 420, and the details are not described again herein to avoid repetition.

In some embodiments, the doping concentration of the heavily doped region 422 may be between 1×10¹⁸ cm⁻³ and 1×10²² cm⁻³. The heavily doped region 422 may be coupled to the subsequently formed source contacts 980S simultaneously with the source region 424-1 and the source region 424-2. The depth of the heavily doped region 422 may be between 0.1 μm and 0.5 μm. According to some embodiments of the present disclosure, since the well region 420 and the heavily doped region 422 have the same conductive type, the heavily doped region 422 may serve as the source terminal main body that connects the source region 424-1 and the source region 424-2, and may play a critical role for the source terminal to be electrically ground.

In some embodiments, the doping concentration of the source region 424-1 and the source region 424-2 may be between 1×10¹⁸ cm⁻³ and 1×10²² cm⁻³. The depth of the source region 424-1 and the source region 424-2 may be between 0.1 μm and 0.5 μm. According to some embodiments of the present disclosure, the source region 424-1 and the source region 424-2 may function as the source terminal for the split-gate transistor.

Referring to FIG. 2, a dielectric layer 520-1, a dielectric layer 520-2, an electrode 680-1, and an electrode 680-2 may be disposed in the epitaxial layer 180. The dielectric layer 520-1 may include a first portion 520-1A and a second portion 520-1B. The dielectric layer 520-2 may include a first portion 520-2A and a second portion 520-2B. The electrode 680-1 may include a first structure 680-1A and a second structure 680-1B. The electrode 680-2 may include a first structure 680-2A and a second structure 680-2B. In some embodiments, the second portion 520-1B and the second structure 680-1B may constitute a gate structure laterally located on one side of the well region 420 close to the source region 424-1, while the second portion 520-2B and the second structure 680-2B may constitute another gate structure laterally located on another side of the well region 420 close to the source region 424-2. Moreover, the first portion 520-1A and the first structure 680-1A may constitute a split-gate structure below the gate structure (including the second portion 520-1B and the second structure 680-1B), while the first portion 520-2A and the first structure 680-2A may constitute another split-gate structure below the gate structure (including the second portion 520-2B and the second structure 680-2B).

In some embodiments, the gate structure (including the second portion 520-1B and the second structure 680-1B) and the gate structure (including the second portion 520-2B and the second structure 680-2B) may be coupled to the subsequently formed gate contacts 980G, respectively. The first structure 680-1A and the second structure 680-1B of the electrode 680-1 may be insulated from each other, and the first structure 680-2A and the second structure 680-2B of the electrode 680-2 may be insulated from each other. According to some embodiments of the present disclosure, the gate structure (including the second portion 520-1B and the second structure 680-1B), the gate structure (including the second portion 520-2B and the second structure 680-2B), the split-gate structure (including the first portion 520-1A and the first structure 680-1A), and the split-gate structure (including the first portion 520-2A and the first structure 680-2A) may be connected to the same electric potential (not shown) as the source terminal of the split-gate transistor.

The materials of the dielectric layer 520-1 and the dielectric layer 520-2 may include silicon oxide (SiO), silicon nitride (SiN), silicon oxynitride (SiON), or a multiple layer thereof. In other embodiments, the dielectric layer 520-1 and the dielectric layer 520-2 may include high-k materials, which have the dielectric constant approximately larger than 7.0. High-k materials may include metal oxides, or silicates of hafnium (Hf), aluminum, zirconium (Zr), lanthanum (La), magnesium (Mg), barium (Ba), titanium (Ti), lead (Pb), the like, or a combination thereof. Metal oxides may include hafnium oxide (HfO₂), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (La₂O₃), aluminum oxide (Al₂O₃), aluminum silicon oxide (AlSiO), zirconium oxide (ZrO₂), titanium oxide (TiO), tantalum oxide (Ta₂O₅), yttrium oxide (Y₂O₃), or the like.

The thickness of the second portion 520-1B of the dielectric layer 520-1 and the second portion 520-2B of the dielectric layer 520-2 may be between 250 Å and 1500 Å. The thickness of the first portion 520-1A of the dielectric layer 520-1 and the first portion 520-2A of the dielectric layer 520-2 may be between 1000 Å and 6000 Å. According to some embodiments of the present disclosure, the thickness of the first portion 520-1A and the first portion 520-2A may be larger than the thickness of the second portion 520-1B and the second portion 520-2B. It should be appreciated that if the thickness of the second portion 520-1B and the second portion 520-2B is too large, then the threshold voltage generated may be too high. If the thickness of the first portion 520-1A and the first portion 520-2A is too small, then the insulating function may be compromised. The dielectric layer 520-1 and the dielectric layer 520-2 may be formed by chemical vapor deposition (CVD), molecular beam deposition (MBD), atomic layer deposition (ALD), plasma-enhanced chemical vapor deposition (PECVD), the like, or a combination thereof.

The materials of the electrode 680-1 and the electrode 680-2 may include amorphous silicon, polysilicon, poly-SiGe, metal nitride (such as titanium nitride (TiN), tantalum nitride (TaN), tungsten nitride (WN), titanium aluminum nitride (TiAlN), or the like), metal silicide (such as nickel silicide (NiSi), cobalt silicide (CoSi), tantalum silicon nitride (TaSiN), or the like), metal carbide (such as tantalum carbide (TaC), tantalum carbonitride (TaCN), or the like), metal oxide, or metals. Metals may include cobalt (Co), ruthenium (Ru), aluminum, palladium (Pd), platinum (Pt), tungsten (W), copper (Cu), titanium, tantalum (Ta), silver (Ag), gold (Au), nickel (Ni), manganese (Mn), zirconium, the like, a combination thereof, or a multiple layer thereof.

In some embodiments, the first portion 520-1A and the first portion 520-2A may be disposed on the opposite sides and the bottom portion of the first structure 680-1A and the first structure 680-2, respectively. The second portion 520-1B and the second portion 520-2B may be disposed on the opposite sides and the bottom portion of the second structure 680-1B and the second structure 680-2B, respectively. Furthermore, the portion of the second portion 520-1B that is on the bottom portion of the second structure 680-1B may be between the first structure 680-1A and the second structure 680-1B, while the portion of the second portion 520-2B that is on the bottom portion of the second structure 680-2B may be between the first structure 680-2A and the second structure 680-2B. In other words, the first structure 680-1A and the second structure 680-1B of the electrode 680-1 may be “split” by a portion of the dielectric layer 520-1, while the first structure 680-2A and the second structure 680-2B of the electrode 680-2 may be “split” by a portion of the dielectric layer 520-2. This demonstrates the “split-gate” feature of the present disclosure.

The first structure 680-1A and the first structure 680-2A may have the lateral dimension between 0.18 μm and 2 μm, and the vertical dimension between 0.8 μm and 10 μm. The second structure 680-1B and the second structure 680-2B may have the lateral dimension between 0.18 μm and 2 μm, and the vertical dimension between 0.3 μm and 2 μm. According to some embodiments of the present disclosure, the lateral dimension of the second structure 680-1B and the second structure 680-2B may be larger than the lateral dimension of the first structure 680-1A and the first structure 680-2A. The vertical dimension of the first structure 680-1A and the first structure 680-2A may be larger than the vertical dimension of the second structure 680-1B and the second structure 680-2B. The electrode 680-1 and the electrode 680-2 may be formed by physical vapor deposition (PVD), atomic layer deposition, plating, sputtering, evaporating, the like, or a combination thereof.

In some embodiments, first openings (not shown) may first be formed extending into the epitaxial layer 180 at opposite sides of the well region 420. After the formation of the first openings, second openings may be formed from the bottom surface of the first openings. The second openings may still be extended in the epitaxial layer 180, and may be vertically spaced apart from the underlying buried layer 200. The lateral dimension of the first openings may be substantially equal to the lateral dimension of the second openings, while the vertical dimension of the second openings may be larger than the vertical dimension of the first openings. The subsequently formed di-electric layer 520-1, dielectric layer 520-2, electrode 680-1, and electrode 680-2 may adopt the profile of the first openings and the second openings. The first openings and the second openings may be formed by the lithography process, followed by the etching process. The lithography process may include photoresist coating, soft baking, exposure, post-exposure baking, development, the like, or a combination thereof. The etching process may include dry etch process, wet etch process, the like, or a combination thereof.

The wet etch process may be isotropic, and may be performed in wet etchants. In some embodiments, suitable etchants for the wet etch process may include sulfuric acid (H₂SO₄), hydrochloric acid (HCl), hydrogen bromide (HBr), ammonia (NH₃), diluted hydrofluoric acid (dHF), hydrofluoric acid (HF), potassium hydroxide (KOH), nitric acid (HNO₃), acetic acid (CH₃COOH), succinic acid (C₄H₆O₄), citric acid (C₆H₈O₇), the like, or a combination thereof, but the present disclosure is not limited thereto.

The dry etch process may include anisotropic plasma etching, such as reactive ion etching (RIE), inductively coupled plasma (ICP), capacitively coupled plasma (CCP), the like, or a combination thereof, but the present disclosure is not limited thereto. The dry etch process may be performed in the environment of the selected process gas. The illustrative process gas may include nitrogen (N₂), ammonia, oxygen (O₂), dinitrogen monoxide (N₂O), argon (Ar), helium (He), hydrogen (H₂), tetrafluoromethane (CF₄), sulfur hexafluoride (SF₆), difluoromethane (CH₂F₂), trifluoromethane (CHF₃), hexafluoroethane (C₂F₆), chlorine (Cl₂), trichloromethane (CHCl₃), carbon tetrachloride (CCl₄), boron trichloride (BCl₃), hydrogen bromide, bromoform (CHBr₃), or the like, but the present disclosure is not limited thereto.

In some embodiments, the first portion 520-1A of the dielectric layer 520-1 and the first portion 520-2A of the dielectric layer 520-2 may be respectively formed in the second openings using any suitable deposition process mentioned above, followed by forming the first structure 680-1A of the electrode 680-1 and the first structure 680-2A of the electrode 680-2 respectively in the remainder of the second openings using any suitable deposition process mentioned above. More specifically, the dielectric material and the electrode material may be sequentially filled into the second openings after performing the etching process to form the second openings, and before removing the lithography pattern. After the second openings are filled, the planarization process (such as chemical mechanical polish (CMP) or etch back) may be performed to remove the lithography pattern, along with the excessive dielectric material and the electrode material. The remainder of the dielectric material and the electrode material then becomes the first portion 520-1A of the dielectric layer 520-1 and the first portion 520-2A of the dielectric layer 520-2, and the first structure 680-1A of the electrode 680-1 and the first structure 680-2A of the electrode 680-2, respectively.

In some embodiments, the second portion 520-1B of the dielectric layer 520-1 and the second portion 520-2B of the dielectric layer 520-2 may be respectively formed in the first openings using any suitable deposition process mentioned above, followed by forming the second structure 680-1B of the electrode 680-1 and the second structure 680-2B of the electrode 680-2 respectively in the remainder of the first openings using any suitable deposition process mentioned above. More specifically, the same dielectric material may be conformally formed on the sidewalls of the first openings, the top surfaces of the first portion 520-1A and the first structure 680-1A, and the top surfaces of the first portion 520-2A and the first structure 680-2A. After that, the first openings may be completely filled with the same electrode material. The same planarization process may be performed to remove the excessive dielectric material and electrode material outside the first openings. After the planarization process, the top surfaces of the epitaxial layer 180, the dielectric material, and the electrode material may be levelled with each other. The remainder of the dielectric material and the electrode material then becomes the second portion 520-1B of the dielectric layer 520-1 and the second portion 520-2B of the dielectric layer 520-2, and the second structure 680-1B of the electrode 680-1 and the second structure 680-2B of the electrode 680-2, respectively.

Still referring to FIG. 2, a blocking dielectric layer 540-1, a blocking dielectric layer 540-2, a blocking electrode 690-1, and a blocking electrode 690-2 may be formed in the epitaxial layer 180. In some embodiments, the blocking dielectric layer 540-1 and the blocking electrode 690-1 may be laterally adjacent to the dielectric layer 520-1 and the electrode 680-1, while the blocking dielectric layer 540-2 and the blocking electrode 690-2 may be laterally adjacent to the dielectric layer 520-2 and the electrode 680-2. The blocking dielectric layer 540-1 and the blocking electrode 690-1 may constitute a first block, while the blocking dielectric layer 540-2 and the blocking electrode 690-2 may constitute a second block.

In some embodiments, the first block may laterally separate the dielectric layer 520-1 and the electrode 680-1 from the subsequently formed drain electrode 700-1, while the second block may laterally separate the dielectric layer 520-2 and the electrode 680-2 from the subsequently formed drain electrode 700-2. According to some embodiments of the present disclosure, the first block and the second block may prevent the electric field of the drain electrode 700-1 and the drain electrode 700-2 from diffusing into the gate terminal of the split-gate transistor (or even reaching the source terminal of the split-gate transistor), respectively. In other embodiments, the first block and the second block may collectively appear to be a single guard ring from top view, in order to separate the drain terminal from the gate terminal.

The blocking electrode 690-1 and the blocking electrode 690-2 may have the lateral dimension between 0.18 μm and 2 μm, and the vertical dimension between 0.8 μm and 10 μm. The dielectric layer 520-1, the dielectric layer 520-2, the blocking dielectric layer 540-1, and the blocking dielectric layer 540-2 may be formed simultaneously. The electrode 680-1, the electrode 680-2, the blocking electrode 690-1, and the blocking electrode 690-2 may be formed simultaneously. In doing so, the process cycle time and the associated cost may be lowered. Therefore, the materials and the formation of the blocking dielectric layer 540-1 and the blocking dielectric layer 540-2 may be similar to those of the dielectric layer 520-1 and the dielectric layer 520-2, and the details are not described again herein to avoid repetition. The materials and the formation of the blocking electrode 690-1 and the blocking electrode 690-2 may be similar to those of the electrode 680-1 and the electrode 680-2, and the details are not described again herein to avoid repetition.

Referring to FIG. 2, the drain electrode 700-1 and the drain electrode 700-2 may be disposed in the epitaxial layer 180. In some embodiments, the drain electrode 700-1 may be laterally adjacent to the first block (including the blocking dielectric layer 540-1 and the blocking electrode 690-1), while the drain electrode 700-2 may be laterally adjacent to the second block (including the blocking dielectric layer 540-2 and the blocking electrode 690-2). The first block may be laterally disposed between the electrode 680-1 and the drain electrode 700-1, while the second block may be laterally disposed between the electrode 680-2 and the drain electrode 700-2. The drain electrode 700-1 and the drain electrode 700-2 may be coupled to the subsequently formed drain contacts 980D, respectively. The drain electrode 700-1 and the drain electrode 700-2 may be the metal sinkers extending within the epitaxial layer 180, and may be in physical contact with the buried layer 200. According to some embodiments of the present disclosure, the buried layer 200, the drain electrode 700-1, and the drain electrode 700-2 may collectively function as the drain terminal for the split-gate transistor. The drain electrode 700-1 and the drain electrode 700-2 may have the lateral dimension between 0.18 μm and 10 μm, and the vertical dimension between 0.5 μm and 10 μm. In a specific embodiment of the present disclosure, the vertical dimension of the drain electrode 700-1 and the drain electrode 700-2 may need to be extended at least through the epitaxial layer 180, in order to electrically connect to the buried layer 200. The materials and the formation of the drain electrode 700-1 and the drain electrode 700-2 may be similar to those of the electrode 680-1 and the electrode 680-2, and the details are not described again herein to avoid repetition. In a specific embodiment of the present disclosure, the material of the drain electrode 700-1 and the drain electrode 700-2 may include tungsten.

In the first region 10A of the split-gate transistor, the source region 424-1, the drain electrode 700-1, and the dielectric layer 520-1 and the electrode 680-1 may form a first transistor, while the source region 424-2, the drain electrode 700-2, and the dielectric layer 520-2 and the electrode 680-2 may form a second transistor. According to some embodiments of the present disclosure, the first transistor and the second transistor of the split-gate transistor may be in parallel with each other. Therefore, the split-gate transistor may appear to be an array-type metal-oxide semiconductor field effect transistor.

As mentioned previously, although the split-gate transistor in the first region 10A may still have the channel in the vertical direction, such channel may terminate at the buried layer 200. The current in the channel may change from the vertical traveling direction to the horizontal travelling direction, in which the current is laterally directed toward the drain electrode 700-1 and the drain electrode 700-2 at both ends. Next, the drain electrode 700-1 and the drain electrode 700-2 may vertically direct the current upward. In other words, the starting point and the ending point of the current may both be located at the frontside surface of the split-gate transistor during the operation of the vertical active element in the first region 10A. Different from a typical vertical active element, the channel of the split-gate transistor in the first region 10A may not be extended to the backside of the semiconductor on insulator substrate 100 in the vertical direction. Therefore, the split-gate transistor in the first region 10A may also be known as a quasi-vertical active element from certain perspectives.

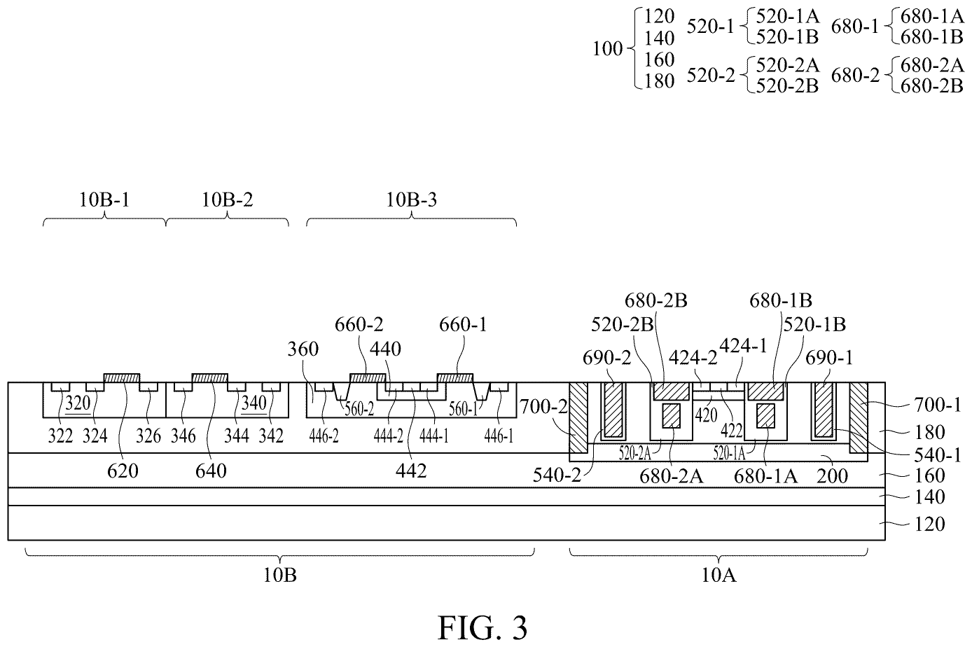

Referring to FIG. 3, the horizontal active element may be disposed in the second region 10B of the semiconductor on insulator substrate 100, and may include a first transistor 10B-1, a second transistor 10B-2, and a third transistor 10B-3. The first transistor 10B-1 may be a metal-oxide semiconductor transistor having the second conductive type (n-type). The second transistor 10B-2 may be a metal-oxide semiconductor transistor having the first conductive type (p-type). The third transistor 10B-3 may be a lateral-diffused metal-oxide semiconductor transistor having the second conductive type (n-type). In some embodiments, the first transistor 10B-1 may be adjoined with the second transistor 10B-2, while the second transistor 10B-2 may be spaced apart from the third transistor 10B-3. Different from the vertical active element in the first region 10A, the first transistor 10B-1, the second transistor 10B-2, and the third transistor 10B-3 may have the channels in the horizontal direction. According to a specific embodiment of the present disclosure, the first transistor 10B-1, the second transistor 10B-2, and the third transistor 10B-3 may constitute the horizontal active element (for example, an integrated bipolar complementary metal oxide semiconductor—double diffused metal oxide semiconductor transistor).

Initially, a well region 320 of the first transistor 10B-1, a well region 340 of the second transistor 10B-2, and a high-voltage well region 360 of the third transistor 10B-3 may be disposed within the epitaxial layer 180. The well region 320, the well region 340, and the high-voltage well region 360 may be extended vertically from the upper surface of the epitaxial layer 180 into the epitaxial layer 180. According to some embodiments of the present disclosure, the well region 320 may be the first conductive type (p-type), while the well region 340 and the high-voltage well region 360 may be the second conductive type (n-type). The well region 320 and the well region 340 may be laterally adjoined with each other, while the well region 340 and the high-voltage well region 360 may be laterally spaced apart from each other. The formation of the well region 320, the well region 340, and the high-voltage well region 360 may be similar to that of the well region 420, and the details are not described again herein to avoid repetition.

In some embodiments, the doping concentration of the well region 320 may be between 1×10¹⁵ cm⁻³ and 2×10¹⁷ cm⁻³. The thickness of the well region 320 may be between 0.3 μm and 1.5 μm. The well region 320 may include the subsequently formed main body region 322, source region 324, and drain region 326. Moreover, a gate structure 620 may be subsequently formed on the surface of the well region 320 in the epitaxial layer 180. The gate structure 620 may be laterally located between the source region 324 and the drain region 326.

In some embodiments, the doping concentration of the well region 340 may be between 1×10¹⁵ cm⁻³ and 2×10¹⁷ cm⁻³. The thickness of the well region 340 may be between 0.3 μm and 1.5 μm. The well region 340 may include the subsequently formed main body region 342, source region 344, and drain region 346. Moreover, a gate structure 640 may be subsequently formed on the surface of the well region 340 in the epitaxial layer 180. The gate structure 640 may be laterally located between the source region 344 and the drain region 346.

In some embodiments, the doping concentration of the high-voltage well region 360 may be between 1×10¹⁵ cm⁻³ and 2×10¹⁷ cm⁻³. The thickness of the high-voltage well region 360 may be between 0.3 μm and 1.5 μm. The high-voltage well region 360 may include the subsequently formed well region 440, drain region 446-1, drain region 446-2, isolation structure 560-1, and isolation structure 560-2. The well region 440 may further include a heavily doped region 442, a source region 444-1, and a source region 444-2. Moreover, a gate structure 660-1 and a gate structure 660-2 may be subsequently formed on the surface of the high-voltage well region 360 in the epitaxial layer 180. The gate structure 660-1 may be laterally located between the source region 444-1 and the drain region 446-1, while the gate structure 660-2 may be laterally located between the source region 444-2 and the drain region 446-2. The isolation structure 560-1 may laterally separate the drain region 446-1 from the gate structure 660-1, while the isolation structure 560-2 may laterally separate the drain region 446-2 from the gate structure 660-2.

Still referring to FIG. 3, the main body region 322, the source region 324, and the drain region 326 may be disposed within the well region 320, which may be extended downward from the upper surface of the well region 320. According to some embodiments of the present disclosure, the main body region 322 may be the first conductive type (p-type), while the source region 324 and the drain region 326 may be the second conductive type (n-type). The main body region 322, the source region 324, and the drain region 326 may be laterally spaced apart. The formation of the main body region 322, the source region 324, and the drain region 326 may be similar to that of the well region 420, and the details are not described again herein to avoid repetition.

In some embodiments, the doping concentration of the main body region 322 may be between 1×10¹⁸ cm⁻³ and 1×10²² cm⁻³. The main body region 322 may be coupled to the subsequently formed main body contact 920B. The thickness of the main body region 322 may be between 0.1 μm and 0.5 μm. According to some embodiments of the present disclosure, since the well region 320 and the main body region 322 have the same conductive type, the main body region 322 may serve as the main body terminal for the first transistor 10B-1.

In some embodiments, the doping concentration of the source region 324 may be between 1×10¹⁸ cm⁻³ and 1×10²² cm⁻³. The source region 324 may be coupled to the subsequently formed source contact 920S. The thickness of the source region 324 may be between 0.1 μm and 0.5 μm. According to some embodiments of the present disclosure, the source region 324 may serve as the source terminal for the first transistor 10B-1.

In some embodiments, the doping concentration of the drain region 326 may be between 1×10¹⁸ cm⁻³ and 1×10²² cm⁻³. The drain region 326 may be coupled to the subsequently formed drain contact 920D. The thickness of the drain region 326 may be between 0.1 μm and 0.5 μm. According to some embodiments of the present disclosure, the drain region 326 may serve as the drain terminal for the first transistor 10B-1.

Referring to FIG. 3, the main body region 342, the source region 344, and the drain region 346 may be disposed within the well region 340, which may be extended downward from the upper surface of the well region 340. According to some embodiments of the present disclosure, the main body region 342 may be the second conductive type (n-type), while the source region 344 and the drain region 346 may be the first conductive type (p-type). The main body region 342, the source region 344, and the drain region 346 may be laterally spaced apart. The formation of the main body region 342, the source region 344, and the drain region 346 may be similar to that of the well region 420, and the details are not described again herein to avoid repetition.

In some embodiments, the doping concentration of the main body region 342 may be between 1×10¹⁸ cm⁻³ and 1×10²² cm⁻³. The main body region 342 may be coupled to the subsequently formed main body contact 940B. The thickness of the main body region 342 may be between 0.1 μm and 0.5 μm. According to some embodiments of the present disclosure, since the well region 340 and the main body region 342 have the same conductive type, the main body region 342 may serve as the main body terminal for the second transistor 10B-2.

In some embodiments, the doping concentration of the source region 344 may be between 1×10¹⁸ cm⁻³ and 1×10²² cm⁻³. The source region 344 may be coupled to the subsequently formed source contact 940S. The thickness of the source region 344 may be between 0.1 μm and 0.5 μm. According to some embodiments of the present disclosure, the source region 344 may serve as the source terminal for the second transistor 10B-2.

In some embodiments, the doping concentration of the drain region 346 may be between 1×10¹⁸ cm⁻³ and 1×10²² cm⁻³. The drain region 346 may be coupled to the subsequently formed drain contact 940D. The thickness of the drain region 346 may be between 0.1 μm and 0.5 μm. According to some embodiments of the present disclosure, the drain region 346 may serve as the drain terminal for the second transistor 10B-2.

Still referring to FIG. 3, the well region 440, the drain region 446-1, the drain region 446-2, the isolation structure 560-1, and the isolation structure 560-2 may be disposed within the high-voltage well region 360, which may be extended downward from the upper surface of the high-voltage well region 360. According to some embodiments of the present disclosure, the well region 440 may be the first conductive type (p-type), while the drain region 446-1 and the drain region 446-2 may be the second conductive type (n-type). The well region 440, the drain region 446-1, and the drain region 446-2 may be laterally spaced apart. The isolation structure 560-1 and the isolation structure 560-2 may be adjoined with the drain region 446-1 and the drain region 446-2, respectively. The formation of the well region 440, the drain region 446-1, and the drain region 446-2 may be similar to that of the well region 420, and the details are not described again herein to avoid repetition.

In some embodiments, the doping concentration of the well region 440 may be between 1×10¹⁵ cm⁻³ and 2×10¹⁸ cm⁻³. The thickness of the well region 440 may be between 0.3 μm and 1.5 μm. The well region 440 may include the subsequently formed heavily doped region 442, source region 444-1, and source region 444-2. Moreover, the gate structure 660-1 and the gate structure 660-2 may be partially in contact with the well region 440.

In some embodiments, the doping concentration of the drain region 446-1 and the drain region 446-2 may be between 1×10¹⁸ cm⁻³ and 1×10²² cm⁻³. The drain region 446-1 and the drain region 446-2 may be coupled to the subsequently formed drain contacts 960D, respectively. The thickness of the drain region 446-1 and the drain region 446-2 may be between 0.1 μm and 0.5 μm. According to some embodiments of the present disclosure, the drain region 446-1 and the drain region 446-2 may serve as the drain terminal for the third transistor 10B-3.

In some embodiments, the isolation structure 560-1 and the isolation structure 560-2 may be shallow trench isolation (STI) structures or local oxidation of silicon (LOCOS) structures. As mentioned previously, the isolation structure 560-1 may laterally separate the drain region 446-1 from the gate structure 660-1, while the isolation structure 560-2 may laterally separate the drain region 446-2 from the gate structure 660-2. According to some embodiments of the present disclosure, the isolation structure 560-1 and the isolation structure 560-2 may prevent the generation of high electric field due to the junction breakdown. The depth of the isolation structure 560-1 and the isolation structure 560-2 may be between 0.2 μm and 0.6 μm. It is worth noted that the depth of the isolation structure 560-1 and the isolation structure 560-2 should be larger than the thickness of the drain region 446-1 and the drain region 446-2, in order to effectively block the high electric field from the drain region 446-1 and the drain region 446-2.

In some embodiments, the formation of the isolation structure 560-1 and the isolation structure 560-2 may include, for example, forming an insulating layer on the semiconductor on insulator substrate 100, selectively etching the insulating layer and the semiconductor on insulator substrate 100 to form trenches that extend from the top surface of the semiconductor on insulator substrate 100 to a position within the semiconductor on insulator substrate 100, in which the trenches are located between adjacent active regions. Next, the rich nitrogen-con-taining (such as silicon oxynitride or the like) liners may be grown along the trenches, followed by filling insulating materials (such as silicon dioxide (SiO₂), silicon nitride, silicon oxynitride, or the like) into the trenches with deposition processes. After that, an annealing process is performed on the insulating materials in the trenches, followed by performing the planarization process (such as chemical mechanical polish or the like) on the semiconductor on insulator substrate 100 to remove excessive insulating materials, so the insulating materials in the trenches are levelled with the top surface of the semiconductor on insulator substrate 100.

Referring to FIG. 3, the heavily doped region 442, the source region 444-1, and the source region 444-2 may be disposed within the well region 440, and may be extended downward from the upper surface of the well region 440. According to some embodiments of the present disclosure, the heavily doped region 442 may be the first conductive type (p-type), while the source region 444-1 and the source region 444-2 may be the second conductive type (n-type). The heavily doped region 442, the source region 444-1, and the source region 444-2 may be laterally adjoined with each other, and the heavily doped region 442 may be laterally sandwiched between the source region 444-1 and the source region 444-2. The formation of the heavily doped region 442, the source region 444-1, and the source region 444-2 may be similar to that of the well region 420, and the details are not described again herein to avoid repetition.

In some embodiments, the doping concentration of the heavily doped region 442 may be between 1×10¹⁸ cm⁻³ and 1×10²² cm⁻³. The heavily doped region 442 may be coupled to the subsequently formed source contacts 960S simultaneously with the source region 444-1 and the source region 444-2. The thickness of the heavily doped region 442 may be between 0.1 μm and 0.5 μm. According to some embodiments of the present disclosure, since the well region 440 and the heavily doped region 442 have the same conductive type, the heavily doped region 442 may serve as the source terminal main body that connects to the source region 444-1 and the source region 444-2, and may play a critical role for the source terminal to be electrically ground.

In some embodiments, the doping concentration of the source region 444-1 and the source region 444-2 may be between 1×10¹⁸ cm⁻³ and 1×10²² cm⁻³. The thickness of the source region 444-1 and the source region 444-2 may be between 0.1 μm and 0.5 μm. According to some embodiments of the present disclosure, the source region 444-1 and the source region 444-2 may function as the source terminal for the third transistor 10B-3.

Still referring to FIG. 3, the gate structure 620 of the first transistor 10B-1, the gate structure 640 of the second transistor 10B-2, and the gate structure 660-1 and the gate structure 660-2 of the third transistor 10B-3 may be disposed on the epitaxial layer 180. The portion of the well region 320 that is in contact with the gate structure 620 may be considered as the channel region for the first transistor 10B-1, and the gate structure 620 may serve as the gate terminal for the first transistor 10B-1. The gate structure 620 may be coupled to the subsequently formed gate contact 920G. The portion of the well region 340 that is in contact with the gate structure 640 may be considered as the channel region for the second transistor 10B-2, and the gate structure 640 may serve as the gate terminal for the second transistor 10B-2. The gate structure 640 may be coupled to the subsequently formed gate contact 940G. The gate structure 660-1 and the gate structure 660-2 may be extended from above the high-voltage well region 360 reaching above the well region 440 in the horizontal direction. The portion of the high-voltage well region 360 or the portion of the well region 440 that is in contact with the gate structure 660-1 and the gate structure 660-2 may be considered as the channel region for the third transistor 10B-3, and the gate structure 660-1 and the gate structure 660-2 may serve as the gate terminal for the third transistor 10B-3. The gate structure 660-1 and the gate structure 660-2 may be coupled to the subsequently formed gate contacts 960G, respectively.

In the third transistor 10B-3, the source region 444-1, the drain region 446-1, and the gate structure 660-1 may form a transistor of the second conductive type (n-type) (known as a first transistor hereafter), while the source region 444-2, the drain region 446-2, and the gate structure 660-2 may form another transistor of the second conductive type (n-type) (known as a second transistor hereafter). According to some embodiments of the present disclosure, the first transistor and the second transistor of the third transistor 10B-3 may be in parallel with each other. Therefore, the third transistor 10B-3 may appear to be an array-type structure, for example, the laterally double diffused metal-oxide semiconductor transistor.

The thickness of the gate structure 620, the gate structure 640, the gate structure 660-1, and the gate structure 660-2 may be between 20 Å and 1000 Å. In some embodiments, each of the gate structure 620, the gate structure 640, the gate structure 660-1, and the gate structure 660-2 may include a gate dielectric layer (not shown) and a gate electrode (not shown) disposed on the gate dielectric layer. The materials and the formation of the gate dielectric layer may be similar to those of the dielectric layer 520-1 and the dielectric layer 520-2, and the details are not described again herein to avoid repetition. The materials and the formation of the gate electrode may be similar to those of the electrode 680-1 and the electrode 680-2, and the details are not described again herein to avoid repetition.

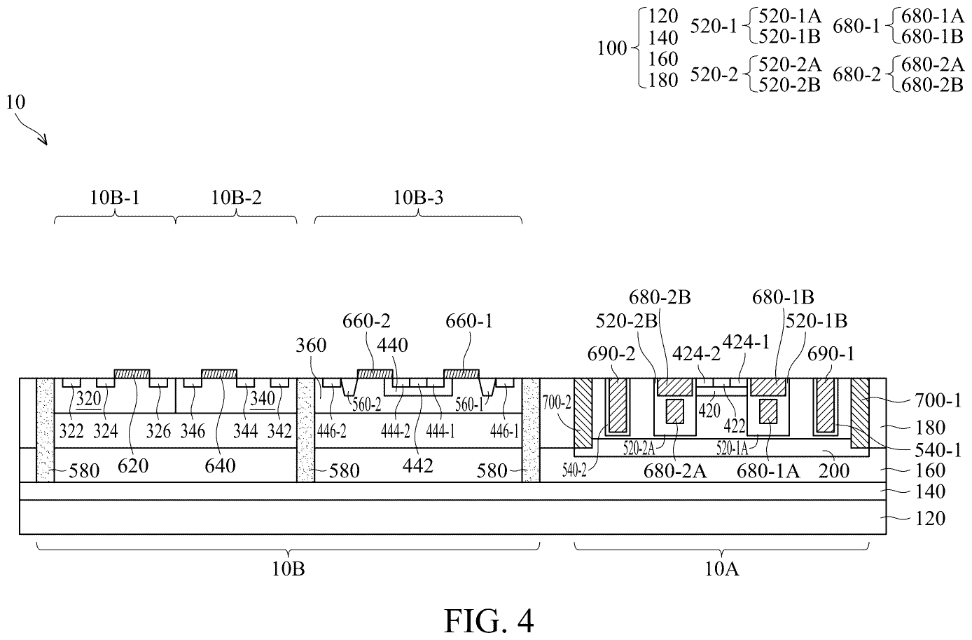

Referring to FIG. 4, an isolation structure 580 may be disposed in the semiconductor on insulator substrate 100 after the formation of the vertical active element of the first region 10A and the horizontal active element of the second region 10B. In some embodiments, the isolation structure 580 may be the deep trench isolation structure. The isolation structure 580 may be extended through the epitaxial layer 180 and the epitaxial layer 160, as well as reaching the insulating layer 140. According to some embodiments of the present disclosure, the isolation structure 580 may laterally surround and define the active regions, and may electrically isolate active region elements within or above the semiconductor on insulator substrate 100. The materials and the formation of the isolation structure 580 may be similar to those of the isolation structure 560-1 and the isolation structure 560-2, and the details are not described again herein to avoid repetition.

It should be appreciated that the isolation structure 580 may be extended into the insulating layer 140, but cannot be extended through the insulating layer 140. A typical bipolar complementary metal oxide semiconductor double diffused metal oxide semiconductor transistor may utilize the junction design to achieve the isolation effect. However, such isolation is not complete. According to some embodiments of the present disclosure, the isolation structure 580 may be combined with the semiconductor on insulator substrate 100 (for example, the insulating layer 140) to achieve the complete isolation effect. As shown in FIG. 4, the isolation structure 580 may laterally surround the horizontal active element (for example, the bipolar complementary metal oxide semiconductor—double diffused metal oxide semiconductor transistor), thereby isolating from other active elements (for example, the split-gate transistor of the first region 10A). Furthermore, the isolation structure 580 may further isolate the first transistor 10B-1 and the second transistor 10B-2 from the third transistor 10B-3. In other words, the isolation structure 580 may completely isolate the “bipolar complementary metal oxide semiconductor” portion from the “double diffused metal oxide semiconductor” portion in the horizontal active element.

From another perspective, the isolation structure 580 and the semiconductor on insulator substrate 100 (for example, the insulating layer 140) may be collectively considered as a “container” that accommodates individual active elements, and may isolate neighboring active elements to suppress potential leakage and unwanted cross interference. Although the semiconductor device 10 only illustrates the isolation structure 580 surrounding the bipolar complementary metal oxide semiconductor—double diffused metal oxide semiconductor transistor of the second region 10B, but the present disclosure is not limited thereto. For example, the isolation structure 580 may be additionally configured to laterally surround the split-gate transistor of the first region 10A, and may be combined with the insulating layer 140 to achieve the complete isolation for the vertical active element of the first region 10A.

Referring to FIG. 5, an interlayer dielectric (ILD) layer 800 may be disposed on the semiconductor on insulator substrate 100. In some embodiments, the interlayer dielectric layer 800 may cover the gate structure 620, the gate structure 640, the gate structure 660-1, and the gate structure 660-2. In addition to providing mechanical protection and electrical insulation for the underlying structures, the interlayer dielectric layer 800 may also isolate conductive materials from different levels. The materials of the interlayer dielectric layer 800 may include silicon oxide, silicon nitride, silicon carbide, silicon oxynitride, silicon oxynitrocarbide (SiOₓN_{y}C_{1-x-y}, wherein x and y are in a range from 0 to 1), tetra ethyl ortho silicate (TEOS), undoped silicate glass, doped silicon oxide (such as boron-doped phosphosilicate glass (BPSG), fused silica glass (FSG), phosphosilicate glass (PSG), boron doped silicate glass (BSG), or the like), low-k dielectric materials, or the like.

The thickness of the interlayer dielectric layer 800 may be between 5000 Å and 20000 Å. The interlayer dielectric layer 800 may be formed by spin-on coating, chemical vapor deposition, high-density plasma chemical vapor deposition (HDP-CVD), plasma-enhanced chemical vapor deposition, low-pressure chemical vapor deposition (LPCVD), flowable chemical vapor deposition (FCVD), sub-atmospheric chemical vapor deposition (SACVD), the like, or a combination thereof. Next, the planarization process (such as chemical mechani-cal polish) may be performed on the interlayer dielectric layer 800, allowing the interlayer dielectric layer 800 to have a planar surface.

Still referring to FIG. 5, the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, the gate contacts 980G, and the drain contacts 980D may be formed through the interlayer dielectric layer 800. In the first transistor 10B-1, the main body contact 920B, the source contact 920S, the drain contact 920D, and the gate contact 920G may physically contact the main body region 322, the source region 324, the drain region 326, and the gate structure 620, respectively. In the second transistor 10B-2, the main body contact 940B, the source contact 940S, the drain contact 940D, and the gate contact 940G may physically contact the main body region 342, the source region 344, the drain region 346, and the gate structure 640, respectively. In the third transistor 10B-3, the source contacts 960S, the drain contacts 960D, and the gate contacts 960G may physically contact the heavily doped region 442 and the source region 444-1/the source region 444-2, the drain region 446-1 and the drain region 446-2, and the gate structure 660-1 and the gate structure 660-2, respectively. In the split-gate transistor of the first region 10A, the source contacts 980S, the gate contacts 980G, and the drain contacts 980D may physically contact the heavily doped region 422 and the source region 424-1/the source region 424-2, the electrode 680-1 and the electrode 680-2, and the drain electrode 700-1 and the drain electrode 700-2, respectively.

The main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, the gate contacts 980G, and the drain contacts 980D may be formed together, thus include the same materials. The materials may be similar to those of the electrode 680-1 and the electrode 680-2, and the details are not described again herein to avoid repetition. Initially, openings may be formed in the interlayer dielectric layer 800 to correspond to the main body region 322, the source region 324, the drain region 326, the gate structure 620, the main body region 342, the source region 344, the drain region 346, the gate structure 640, the heavily doped region 442 and the source region 444-1/the source region 444-2, the drain region 446-1 and the drain region 446-2, the gate structure 660-1 and the gate structure 660-2, the heavily doped region 422 and the source region 424-1/the source region 424-2, the electrode 680-1 and the electrode 680-2, and the drain electrode 700-1 and the drain electrode 700-2. Next, the materials mentioned above may be blanket deposited on the inter-layer dielectric layer 800 through the suitable deposition process. The materials mentioned above may be filled into the openings to form the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, the gate contacts 980G, and the drain contacts 980D.

In some embodiments, although the present disclosure only describes up to the manufacturing process of the main body contact 920B, the source contact 920S, the drain contact 920D, the gate contact 920G, the main body contact 940B, the source contact 940S, the drain contact 940D, the gate contact 940G, the source contacts 960S, the drain contacts 960D, the gate contacts 960G, the source contacts 980S, the gate contacts 980G, and the drain contacts 980D, but the present disclosure is not limited thereto. According to the requirements of the industry, any subsequent process may be performed using the structure shown in FIG. 5 as the basis. For example, the suitable back-end of line (BEOL) process may be performed above the semiconductor device 10, not shown for simplicity.

In the present technology, the channel of the horizontal active element may be extended in the horizontal direction, while the channel of the vertical active element may be extended in the vertical direction. Therefore, if the horizontal active element and the vertical active element are to be disposed onto the same wafer, the horizontal active element and the vertical active element need to be formed in different manufacturing processes. Furthermore, since it is already difficult to achieve the effective isolation in the horizontal active element, the isolation may be even more challenging when the horizontal active element and the vertical active element are integrated. According to some embodiments of the present disclosure, the semiconductor on insulator substrate may be combined with the deep trench isolation structure to achieve the complete isolation. The deep trench isolation structure and the semiconductor on insulator substrate may be collectively considered as the “container” that accommodates the individual active elements, and may isolate neighboring active elements to suppress potential leakage and unwanted cross interference. Moreover, in response to the implementation of the semiconductor on insulator substrate, the innovative drain terminal of the vertical active element may be constituted by electrically connecting the metal sinkers with the buried layer. The vertical active element may have the channel in the vertical direction, which may terminate at the buried layer. The current in the channel may change from the vertical travelling direction to the horizontal travelling direction, in which the current is laterally directed toward the metal sinkers at both ends. Next, the metal sinkers may vertically direct the current upward. In other words, the starting point and the ending point of the current may both be located at the frontside surface of the vertical active element. The vertical active element of the present disclosure may also be known as the quasi-vertical active element from certain perspectives. Therefore, the horizontal active element and the vertical active element may be effectively integrated to achieve the complete isolation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor on insulator (SOI) substrate;
a vertical active element disposed in a first region of the semiconductor on insulator substrate, comprising:
a pair of source regions disposed in the semiconductor on insulator substrate;
a pair of gate electrodes disposed at opposite sides of the pair of source regions, respectively;
a pair of drain electrodes disposed at opposite sides of the pair of gate electrodes, respectively; and
a buried layer located below the pair of source regions and the pair of gate electrodes, and electrically connected to the pair of drain electrodes;
a horizontal active element disposed in a second region of the semiconductor on insulator substrate; and
an isolation structure separating the vertical active element from the horizontal active element.

2. The semiconductor device of claim 1, wherein the vertical active element is a discrete device, and the horizontal active element is a bipolar complementary metal oxide semiconductor—double diffused metal oxide semiconductor (BCD) transistor.

3. The semiconductor device of claim 2, wherein the discrete device comprises a split-gate transistor (SGT).

4. The semiconductor device of claim 2, further comprising a heavily doped region sandwiched between the pair of source regions, wherein the heavily doped region has a first conductive type, while the pair of source regions has a second conductive type different from the first conductive type.

5. The semiconductor device of claim 4, wherein the heavily doped region laterally adjoins the pair of source regions.

6. The semiconductor device of claim 4, wherein the heavily doped region and the pair of source regions are disposed in a well region, wherein the well region has the first conductive type.

7. The semiconductor device of claim 4, wherein the semiconductor on insulator substrate further comprising:
a base plate having the second conductive type;
an insulating layer disposed on the base plate; and
a first epitaxial layer disposed on the insulating layer, and having the second conductive type.

8. The semiconductor device of claim 7, wherein the insulating layer continuously extends across the first region and the second region.

9. The semiconductor device of claim 7, wherein the semiconductor on insulator substrate further comprising a second epitaxial layer disposed between the insulating layer and the first epitaxial layer, and having the second conductive type.

10. The semiconductor device of claim 9, wherein the buried layer is disposed within the second epitaxial layer.

11. The semiconductor device of claim 10, wherein the buried layer extends upward from the interface between the second epitaxial layer and the first epitaxial layer.

12. The semiconductor device of claim 11, wherein the pair of drain electrodes is a pair of metal sinkers extending through the first epitaxial layer and in physical contact with the buried layer.

13. The semiconductor device of claim 9, wherein the isolation structure is a deep trench isolation (DTI) structure extending through the first epitaxial layer and the second epitaxial layer, and reaching the insulating layer.

14. The semiconductor device of claim 1, further comprising a pair of blocks laterally separating the pair of drain electrodes from the pair of gate electrodes.

15. The semiconductor device of claim 1, wherein the pair of gate electrodes further comprising:
a first structure having a first dimension; and
a second structure on the first structure, wherein the second structure has a second dimension larger than the first dimension.

16. The semiconductor device of claim 15, further comprising a gate dielectric layer, comprising:
a first portion disposed on opposite sides and a bottom portion of the first structure; and
a second portion disposed between the first structure and the second structure, and on opposite sides of the second structure.

17. The semiconductor device of claim 4, wherein the horizontal active element further comprising:
a first transistor having the second conductive type;
a second transistor adjoining the first transistor, and having the first conductive type; and
a third transistor separating from the second transistor by the isolation structure, and having the second conductive type.

18. The semiconductor device of claim 17, wherein the first transistor and the second transistor are metal-oxide semiconductor (MOS) transistors, while the third transistor is a lateral-diffused metal-oxide semiconductor (LDMOS) transistor.

19. The semiconductor device of claim 18, wherein the first transistor, the second transistor, and the third transistor constitute the bipolar complementary metal oxide semiconductor—double diffused metal oxide semiconductor transistor.

20. The semiconductor device of claim 1, further comprising:
a pair of source contacts disposed through an interlayer dielectric (ILD) layer and in physical contact with the pair of source regions;
a pair of gate contacts disposed through the interlayer dielectric layer and in physical contact with the pair of gate electrodes; and
a pair of drain contacts disposed through the interlayer dielectric layer and in physical contact with the pair of drain electrodes.
